(19) United States
(12) Patent Application Publication
(10) Pub. No.: US 2011/0064885 A1
(43) Pub. Date: Mar. 17, 2011

(54) APPARATUS AND METHOD FOR FILM DEPOSITION

(76) Inventors: Kunihiko SUZUKI, Shizuoka (JP); Shinichi MITANI, Shizuoka (JP)

(21) Appl. No.: 12/881,516

(22) Filed: Sep. 14, 2010

(30) Foreign Application Priority Data
Sep. 17, 2009 (JP) 2009-216289

(51) Int. Cl. B05D 3/02; C23C 16/00

(52) U.S. Cl. 427/532; 118/725

(57) ABSTRACT

The deposition apparatus 100 comprises: a heater 121 for heating a silicon wafer 101; electrically-conductive busbars 123 for supporting the heater 121; electrode assemblies 107 for supporting the busbars 123 and conducting electricity to the heater 121, the electrode assemblies 107 each having a hollow rod electrode 108 with upper and lower openings; and a columnar support 105 for supporting the rod electrodes 108 of the electrode assemblies 107. Wafer heating by the heater 121 is conducted while a purge gas flows through the inside of the rod electrodes 108 from the lower openings of the rod electrodes 108, so that the electrode assemblies 107 cannot be heated to a high temperature.

### BACKGROUND OF THE INVENTION

1. Field of the Invention

The present invention relates to an apparatus and a method for film deposition.

2. Background Art

A single-wafer deposition apparatus is often used to deposit a monocrystalline film, such as a silicon film or the like, on a substrate wafer, thereby forming an epitaxial wafer.

FIG. 3 is a schematic cross section of a conventional deposition apparatus 200.

The deposition apparatus 200 comprises the following components: a chamber 201; a base 202 on which to place the chamber 201; a gas inlet port 215 for supplying a deposition gas 204 into the chamber 201; and wafer heating means 205 for heating a wafer 203 on which to deposit a film. Inside the base 202 is a hollow columnar support 206 that extends upwardly into the chamber 201.

Attached to the upper and lower ends of the hollow columnar support 206 are, respectively, the wafer heating means 205 and an electrode securing unit 207, the latter of which serves as a lower lid for closing the lower end of the columnar support 206. Inside the columnar support 206 are two rod electrodes 208 which extend through the electrode securing unit 207 and are thus secured to the columnar support 206. The two rod electrodes 208 penetrate the upper end of a columnar support 206, extending up to the wafer heating means 205 located inside the chamber 201.

The wafer heating means 205 comprises a heater 209 and two electrically-conductive busbars 210 for supporting the heater 209. Each of busbars 210 is secured to a connector 211 that is connected to the upper end of the columnar support 206, a heater 209 is connected to the columnar support 206 via the connectors 211 and the busbars 210. Further, the two rod electrodes 208 are each connected to one of the connectors 211. Therefore, electricity can be conducted from the two rod electrodes 208 to the heater 209. The upper hollow end of the columnar support 206 is also closed by an upper lid 212.

A susceptor 220 on which to place the wafer 203 is installed inside the chamber 201. The susceptor 220 can be rotated. That is, a hollow rotary shaft 221 surrounds the hollow columnar support 206. The rotary shaft 221 is attached to the base 202 such that the rotary shaft 221 can rotate around the columnar support 206 via a bearing not illustrated. The rotation of the rotary shaft 221 is achieved by a motor 222.

A rotary drum 223 is installed on the upper end of the rotary shaft 221 that extends upwardly into the chamber 201. Installed on the top surface of the rotary drum 223 is a susceptor 220 on which to place the wafer 203. Therefore, the susceptor 220 inside the chamber 201 can be rotated above the wafer heating means 205 by the motor 222 rotating the rotary shaft 221 and the rotary drum 223.

During the deposition process by the above apparatus 200, the heater 209 of the wafer heating means 205, located below the susceptor 220, heats the wafer 203 on the susceptor 220 while the wafer 203 is being rotated. The apparatus 200 then supplies the deposition gas 204 through the gas inlet port 215, thereby depositing an epitaxial film on the wafer 203.

During such vapor-phase deposition, the heating by the wafer heating means 205 may cause the temperature of the wafer 203 to become extremely hot (higher than 1000 degrees Celsius).

JP-A-5-152207 also discloses a deposition apparatus similar to the above, in which a single wiring component penetrates a lower lid of a hollow columnar support and is secured to the columnar support at its upper and lower sections.

As stated above, the inside of the chamber 201 is exposed to an extremely high temperature at the time of wafer heating during vapor-phase deposition. Thus, the components of the deposition apparatus 200 need to be formed of highly heat-resistant materials.

Regarding the wafer heating means 205, the heater 209, subject to the highest temperature, is typically formed of high-purity silicon carbide (SiC), and the electrically-conductive busbars 210 for supporting the heater 209 are of SiC-coated carbon. These SiC and SiC-coated carbon materials, though low in flexibility and prone to cracking, are typically used because they are less likely to cause metal contamination during wafer heating. In other words, it is of greater importance to select a material for wafer heating means that prevents metal contamination during wafer heating rather than whether or not the material is high in flexibility and heat resistance.

Regarding the rod electrodes 208 inside the hollow columnar support 206, on the other hand, it is more important to ensure and improve electrical conductivity because the rod electrodes 208 are subject to lower temperatures than the heater 209 and its nearby components. Thus, the rod electrodes 208 are typically formed of metallic molybdenum; such rod-shaped molybdenum electrodes excel in electrical conductivity and rigidity.

However, the rod electrodes 208 are sometimes exposed to high temperatures (700 to 800 degrees Celsius or higher) within the chamber 201. In such a case, impurities may be released from the metallic molybdenum that constitutes the rod electrodes 208, or the molybdenum may thermally decompose itself; in either case, the wafer 203 is likely to be contaminated.

Therefore, conventional apparatuses or methods for film deposition are not satisfactory for preventing metal contamination of wafers, which inevitably calls for a new deposition apparatus and method.

The present invention has been contrived to address the above issues. That is, one object of the present invention is to provide a film deposition apparatus that prevents, at the time of heating a wafer, contamination of the wafer, which is attributable to the metal rod electrodes located inside a hollow columnar support that extends into a chamber.

Another object of the present invention is to provide an apparatus and method for film deposition that prevent, during wafer heating, the metal rod electrodes located inside a hollow columnar support that extends into a chamber from being heated to high temperatures.

Other challenges and advantages of the present invention are apparent from the following description.

### SUMMARY OF THE INVENTION

According to one aspect of the present invention, a film deposition apparatus comprises a chamber; a susceptor for placing thereon a substrate, the susceptor being located inside the chamber; a heater for heating the substrate; an electrically-conductive busbar for supporting the heater; a rotary drum for supporting the susceptor at an upper section thereof and for housing the heater and the busbar, and a rotary shaft, located at a lower section of the chamber, for rotating the rotary drum.

The rotary shaft houses an electrode assembly for conducting electricity through the busbar to the heater and a columnar support for supporting the electrode assembly.

The electrode assembly includes a rod electrode and an electrically-conductive connector, attached to an upper end section of the rod electrode, for supporting the busbar.

The rod electrode is a hollow cylindrical shape having upper and lower openings. A purge gas is fed from the lower opening of the rod electrode so that the purge gas can pass through the inside of the rod electrode and be discharged from the upper opening of the rod electrode into the rotary drum.

According to another aspect of the present invention, in a method for depositing a film on a surface of a substrate, the substrate is placed on a susceptor installed on a rotary drum housed by in chamber; the substrate is heated while rotating the rotary drum by a rotary shaft provided at a lower section of the chamber; a deposition gas is fed into the chamber.

A heater is provided inside the rotary drum.

The substrate is heated by conducting electricity to the heater with the use of a hollow rod electrode having upper and lower openings, while feeding a purge gas from the lower opening of the rod electrode so that the purge gas can flow through the inside of the rod electrode.

### BRIEF DESCRIPTION OF THE DRAWINGS

FIG. 1 is a schematic cross section of a film deposition apparatus according to an embodiment of the present invention.

FIG. 2 is a bottom view schematically illustrating the bottom structure of a rotary drum of the deposition apparatus according to the embodiment of the present invention.

FIG. 3 is a schematic cross section of a conventional deposition apparatus.

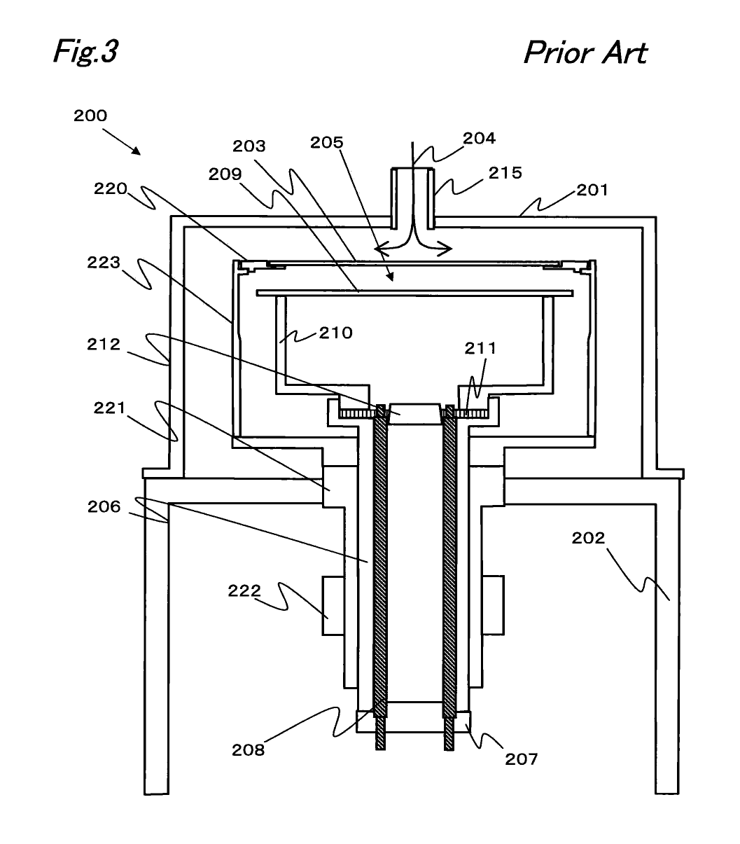

### DETAILED DESCRIPTION OF THE EMBODIMENTS

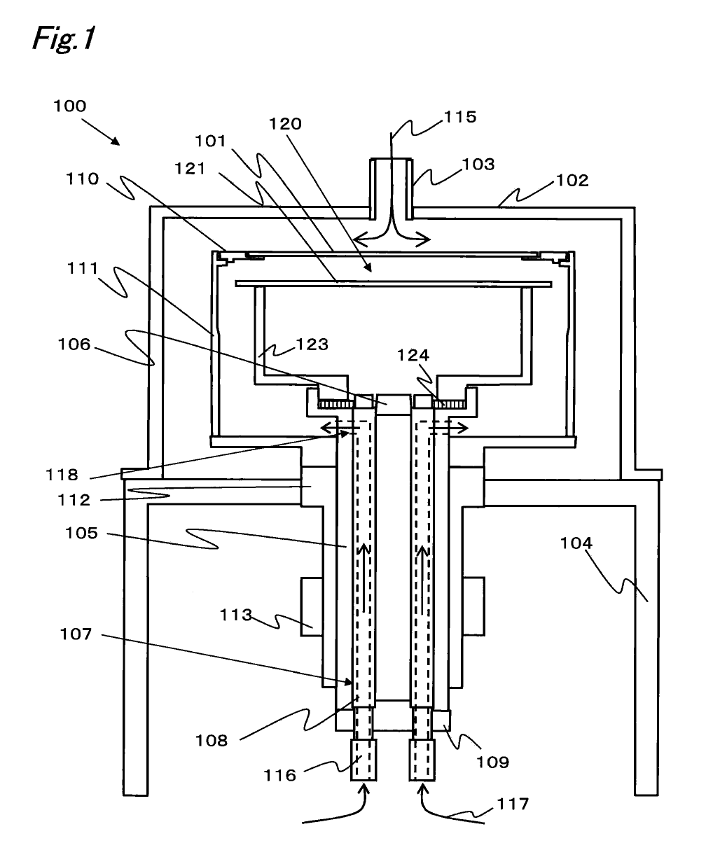

FIG. 1 is a schematic cross section of a film deposition apparatus 100 according to an embodiment of the present invention. In this preferred embodiment, a silicon wafer 101 is used as a substrate on which to deposit a film. Of course, it is also possible to use other wafers formed of different materials if so required.

The deposition apparatus 100 includes a deposition chamber 102 inside which a film is deposited on the wafer 101 and a base 104 on which to place the deposition chamber 102. Inside the base 104 is a non-electrically-conductive, hollow, columnar support 105 that extends upwardly into the chamber 102.

An upper portion of the chamber 102 is provided with a deposition gas inlet port 103. The inlet port 103 is designed to supply a deposition gas 115 after the wafer 101 is heated, so that a crystalline film can be deposited on the top surface of the wafer 101. In the film deposition apparatus 100 of the present embodiment, trichlorosilane is used as the deposition gas 115. After mixed with a hydrogen gas, which acts as a carrier gas, the deposition gas 115 is fed through the gas inlet port 103 into the chamber 102.

Although not illustrated, a flow straightening vane with multiple through holes may be provided on the upstream side of the flow direction of the deposition gas 115 (the direction is illustrated by the topside arrows of FIG. 1). The deposition gas 115 is fed through the inlet port 103 and directed toward the top surface of the wafer 101.

The chamber 102 houses a hollow rotary drum 111, and a susceptor 110 on which to place the wafer 101 is provided on the top surface of the rotary drum 111. The rotary drum 111 is supported by a hollow rotary shaft 112 and houses an upper portion of the hollow columnar support 105, which protrudes from the base 104.

A rotary shaft 112 is attached to a base 104 so that the rotary shaft 112 can rotate around the columnar support 105 via a bearing not illustrated. The rotation of the rotary shaft 112 is achieved by a motor 113. When the motor 113 causes the rotary shaft 112 to rotate, a rotary drum 111 attached to the rotary shaft 112 also starts to rotate, and so does the susceptor 110 attached to the rotary drum 111.

The upper hollow end of the columnar support 105 is closed by an upper lid 106, and wafer heating means 120 is provided above the columnar support 105.

Although not illustrated, a radiation thermometer is provided at an upper section outside the chamber 102 to measure the surface temperature of the wafer 101 while the wafer 101 is being heated. It is preferred that the chamber 102 and the flow straightening vane (not illustrated) be formed of quartz because, as known in the art, the use of quartz prevents the chamber 102 and the flow straightening vane from affecting the temperature measurement by the radiation thermometer. After the temperature measurement, its data is sent to a control device not illustrated.

The control device controls the operation of a three-way valve (not illustrated) installed inside a path through which the hydrogen gas flows. Specifically, when the temperature of the wafer 101 reaches or exceeds a particular value, the control device activates the three-way valve to control the supply of the hydrogen gas to the chamber 102. The control device also controls the output of a heater 121.

The main components of the film deposition apparatus 100 will now be described more in detail.

As illustrated in FIG. 1, the upper portion of the columnar support 105 which is located above the main cylindrical structure of the support 105 can be shaped to have a ring or flange structure whose diameter is greater than the outer diameter of the main cylindrical structure of the support 105. The ring or flange structure can also be provided with an upwardly extending rim around its outer circumference, as is also illustrated in FIG. 1. Shaping the upper portion of the columnar support 105 as above allows reliable attachment of the wafer heating means 120, which will later be described in detail.

Installed inside the hollow columnar support 105 are two electrode assemblies 107. Each of the electrode assemblies 107 includes a hollow rod electrode 108 formed of metallic molybdenum (Mo) and also includes an electrically-conductive connector 124, fixed to the upper end of the rod electrode 108, for supporting an electrically-conductive busbar 123.

The molybdenum rod electrodes 108 are each shaped like a hollow cylinder as stated above, and the lower hollow end of each of the rod electrodes 108 communicates with a purge gas supply port 116 from which to supply a purge gas 117. The upper end of each of the rod electrodes 108, on the other hand, is connected to and closed by the connector 124. As illustrated in FIG. 1, an opening 118 is provided at an upper side section of each of the rod electrodes 108, which section is located inside the rotary drum 111. The columnar support 105 also has through holes, located inside the rotary drum 111, that communicate with the openings 118 of the rod electrodes 108.

Thus, the openings 118 of the hollow rod electrodes 108 act as outlet ports through which to supply the purge gas 117 from the lower openings of the rod electrodes 108. Specifically, when the purge gas 117 is fed through the lower openings of the rod electrodes 108 from the purge gas supply ports 116, the purge gas 117 moves upward through the rod electrodes 108, then passes through the openings 118 of the rod electrodes 108 and through the through holes of the columnar support 105, and is eventually discharged into the rotary drum 111 located inside the chamber 102.

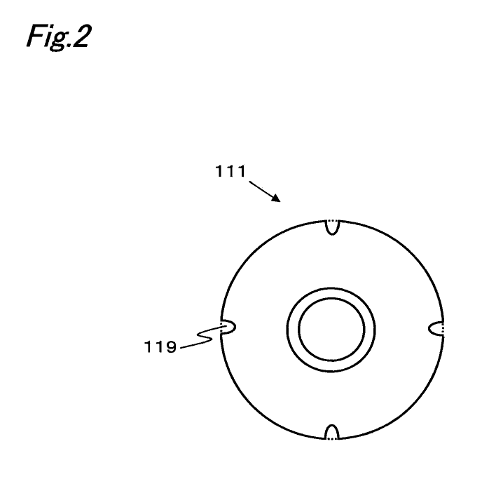

FIG. 2 is a bottom view schematically illustrating the bottom structure of the rotary drum 111 of the deposition apparatus 100.

As illustrated in FIG. 2, multiple outlet ports 119 extend through the bottom section of the rotary drum 111. The outlet ports 119 are designed to discharge the purge gas 117 from the rotary drum 111 into the chamber 102 when the purge gas 117 is fed into the rotary drum 111 through the openings 118 of the rod electrodes 108 and through the through holes of the columnar support 105. After the deposition process, the purge gas 117 is discharged, together with the deposition gas 115, out of the chamber 102 through an exhaust port (not illustrated) of the chamber 102.

The supply of the purge gas 117 from the purge gas supply ports 116 is also controlled by the above-mentioned control device (not illustrated), which, as stated above, controls the supply of the hydrogen gas to the chamber 102. Thus, the hydrogen gas can be used both as the purge gas 117 and as the carrier gas for the deposition gas 115. It is also possible for the control device to use another purge gas source (not illustrated) to supply an inert gas, such as nitrogen gas and argon gas, as the purge gas 117.

To deposit a silicon crystalline film on a wafer, it is preferred to use a hydrogen gas or a nitrogen gas as the purge gas 117. To deposit a silicon carbide (SiC) crystalline film at 1600 degrees Celsius, it is preferred to use a less reactive argon gas as the purge gas 117. When depositing a film of gallium nitride (GaN), on the other hand, it is preferred to use a hydrogen gas as the purge gas 117.

As stated above, the purge gas 117 is fed from the lower openings of the hollow rod electrodes 108 to let it pass through the rod electrodes 108. This makes it possible to cool the rod electrodes 108 so that the rod electrodes 108 cannot be heated to a high temperature during wafer heating and also to control the temperatures of the rod electrodes 108 so that the temperatures do not reach the range of 700 to 800 degrees Celsius, in which contaminants are likely to be released from the rod electrodes 108 formed of molybdenum.

It should be noted that the reason the openings 118 through which to discharge the purge gas 117 are provided at the upper side sections of the rod electrodes 108 is to efficiently cool electrode assemblies 107 each comprising a connector 124 and a rod electrode 108.

The openings 118 at the upper side sections of the rod electrodes 108 also help prevent the purge gas 117 from being directed to the vicinity of the wafer 101 located at an upper section of the rotary drum 111 after the purge gas 117 has passed through the rod electrodes 108. Note also that the reason the purge gas 117 is discharged from the outlet ports 119 of the bottom section of the rotary drum 111 into the chamber 102 is to prevent the purge gas 117 from moving upward inside the rotary drum 111, so that the purge gas 117 cannot contaminate the silicon wafer 101.

In the present embodiment, we set the outer diameter of each of the rod electrodes 108 to 8 mm and the inner diameter of each (i.e., the diameter of the hollow portion of each) to 4 mm. The outer diameter is set to a value that allows the columnar support 105 to house the rod electrodes 108. The inner diameter is determined such that the purge gas 117 can flow smoothly inside the rod electrodes 108 and such that the rod electrodes 108 can maintain sufficient electrical conductivity. It is preferred in the present embodiment that the outer diameter of each of the rod electrodes 108 be from 6 mm to 10 mm and the inner diameter of each from 2 mm to 6 mm.

With the above configuration of the rod electrodes 108 and their nearby components, it is possible to prevent the metal rod electrodes 108 from being heated to an extremely high temperature at the time of heating the silicon wafer 101, thereby preventing metal contamination of the wafer 101 by the rod electrodes 108.

The connectors 124 of the electrode assemblies 107 are shaped such that the connectors 124 extend toward the outer circumference of the columnar support 105 from the upper ends of the rod electrodes 108. Thus, the electrode assemblies 107, each comprising a connector 124 and a rod electrode 108, are L-shaped. Each of the connectors 124 is also formed of metallic molybdenum, meaning the entire electrode assemblies 107 are formed of metallic molybdenum.

With reference again to FIG. 1, an electrode securing unit 109 is attached to the lower end of the columnar support 105. The electrode securing unit 109 secures the rod electrodes 108, which extend upwardly through the electrode securing unit 109. The electrode securing unit 109 also serves as a lower lid for closing the lower end of the hollow columnar support 105.

The wafer heating means 120 comprises the following components: the heater 121 for heating the silicon wafer 101; and the two arm-like busbars 123 for supporting the heater 121. The lower ends of the busbars 123 are attached to the connectors 124 via bolts or the like, as illustrated in FIG. 2.

The heater 121 is formed of silicon carbide (SiC), and the two busbars 123 for supporting the heater 121 are electrically conductive and formed of a SiC-coated carbon material, for example. Since both the connectors 124 and the rod electrodes 108 are formed of molybdenum as stated above, electricity can be conducted from the electrode assemblies 107 through the busbars 123 to the heater 121.

The lower surfaces of the connectors 124 are at least partially in contact with the top surface of the upper portion of the columnar support 105, which portion protrudes from the main cylindrical structure of the support 105. Further, at least one of each of the busbars 123 and each of the connectors 124 is in contact with the upwardly extending rim of the upper portion of the columnar support 105 at two points at least.

Since the electrode securing unit 109 is attached to the lower end of the columnar support 105, that is, located outside the chamber 102, it is less exposed to high temperatures. Thus, the material for the electrode securing unit 109 can be selected from among a relatively wide range of materials. It is preferred to use a material which is moderate in thermal resistance and flexibility. An example of such a material is resin, and a fluorine resin is particularly preferred because it is less subject to degradation under the above temperature environment.

Described next is a method for film deposition of the present invention. Deposition of a silicon epitaxial film on the silicon wafer 101 takes the following steps.

The wafer 101 is first loaded into the chamber 102. The wafer 101 is placed on the susceptor 110, and the rotary drum 111 then starts rotation to rotate the wafer 101 at 50 rpm or thereabout.

Next, the heater 121 is activated to heat the wafer 101 gradually up to, for example, 1150 degrees Celsius, a film deposition temperature. After the radiation thermometer (not illustrated) registers, 1150 degrees Celsius, meaning that the temperature of the wafer 101 has reached that value, then, the rotational speed of the wafer 101 is increased gradually. Thereafter, the deposition gas 115 is fed from the deposition gas inlet port 103 via the flow straightening vane (not illustrated) and directed toward the top surface of the wafer 101.

When the heater 121 starts heating the wafer 101, the purge gas 117 (hydrogen gas) is introduced into the hollow rod electrodes 108 through the purge gas supply ports 116 as instructed by the control device (not illustrated), so that the hydrogen gas can cool the rod electrodes 108. The hydrogen gas passed through the hollow rod electrodes 108 can cool the electrode assemblies 107.

Even after the supply of the deposition gas 115, the radiation thermometer continues to measure the temperature of the wafer 101, and after the temperature reaches a particular value, the control device activates the three-way valve (not illustrated) to control the supply of the carrier gas (hydrogen gas) into the chamber 102.

After an epitaxial film of a particular thickness is deposited on the wafer 101, the supply of the deposition gas 115 is stopped. The supply of the carrier gas can also be stopped at the same time; alternatively, it can also be stopped after the temperature of the wafer 101, as measured by the radiation thermometer, becomes lower than a particular value. After the deposition process, the supply of the purge gas 117 to the rod electrodes 108 is also stopped when the temperature of the wafer 101 becomes lower than a particular value.

Finally, the wafer 101 is transferred out of the chamber 102 after the temperature of the wafer 101 is reduced to a particular value.

The features and advantages of the present invention may be summarized as follows.

In accordance with the first embodiment of the invention, it is possible to provide a film deposition apparatus that prevents, at the time of heating a wafer, the metal rod electrodes located inside a hollow columnar support that extends into a chamber from being heated to a high temperature, so that the wafer cannot be contaminated by the metal rod electrodes.

In accordance with the second embodiment of the invention, it is possible to provide a film deposition method that prevents, at the time of heating a wafer, the metal rod electrodes located inside a hollow columnar support that extends into a chamber from being heated to a high temperature, so that the wafer cannot be contaminated by the metal rod electrodes.

The present invention is not limited to the above-described embodiments but can be embodied in various forms without departing from the scope of the invention. The epitaxial deposition apparatus employed in the first embodiment is only meant to be an example of a film deposition apparatus, and the invention is not limited thereto. Any other apparatus can be used as long as it is capable of depositing a film on a surface of a substrate by feeding a deposition gas into its chamber and heating the substrate inside the chamber.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2009-216289, filed on Sep. 17, 2009 including specification, claims, drawings and summary, on which the Convention priority of the present application is based, are incorporated herein.

What is claimed is:

1. A film deposition apparatus comprising:
a chamber;
a susceptor for placing thereon a substrate, the susceptor being located inside the chamber;
a heater for heating the substrate;
an electrically-conductive busbar for supporting the heater;
a rotary drum for supporting the susceptor at an upper section thereof and for housing the heater and the busbar; and
a rotary shaft, located at a lower section of the chamber, for rotating the rotary drum, the rotary shaft housing:
an electrode assembly for conducting electricity through the busbar to the heater; and
a columnar support for supporting the electrode assembly,
wherein the electrode assembly includes a rod electrode and an electrically-conductive connector, attached to an upper end section of the rod electrode, for supporting the busbar,
wherein the rod electrode is shaped to have a hollow cylindrical shape with upper and lower openings, and
wherein a purge gas is fed from the lower opening of the rod electrode so that the purge gas can pass through the inside of the rod electrode and be discharged from the upper opening of the rod electrode into the rotary drum.

2. The apparatus of claim 1, wherein the hollow rod electrode has an outer diameter of 6 mm to 10 mm and an inner diameter of 2 mm to 6 mm.

3. The apparatus of claim 1, wherein the rod electrode and the connector are each formed of metal.

4. The apparatus of claim 3, wherein the rod electrode is formed of metallic molybdenum.

5. The apparatus of claim 3, wherein the connector is formed of metallic molybdenum.

6. The apparatus of claim 1, wherein the columnar support has a through hole that communicates with the upper opening of the rod electrode and wherein the purge gas fed into the rod electrode flows into the rotary drum by passing through the upper opening of the rod electrode and through the through hole of the columnar support.

7. The apparatus of claim 1, wherein at least one of a lower side section and a bottom section of the rotary drum is provided with an outlet port that extends through the rotary drum and wherein the purge gas, after flowing into the rotary drum through the rod electrode, is discharged through the outlet port into the chamber.

8. The apparatus of claim 1, wherein the purge gas includes at least one gas selected from the group consisting of a hydrogen gas, a nitrogen gas, and an inert gas.

9. A method for depositing a film onto a surface of a substrate, the method comprising the steps of:
placing the substrate on a susceptor installed on a rotary drum housed by a chamber;
heating the substrate while rotating the rotary drum by a rotary shaft provided at a lower section of the chamber; and
feeding a deposition gas into the chamber,
wherein a heater is provided inside the rotary drum and
wherein the substrate is heated by conducting electricity to the heater with the use of a hollow rod electrode having upper and lower openings, while feeding a purge gas from the lower opening of the rod electrode so that the purge gas can flow through the inside of the rod electrode.

10. The method of claim 9, wherein the supply of the purge gas into the rod electrode starts substantially at the same time as the start of heating the substrate.

11. The method of claim 9, wherein the supply of the purge gas into the rod electrode is terminated when the substrate has been cooled after the film deposition.

12. The method of claim 9, wherein the hollow rod electrode has an outer diameter of 6 mm to 10 mm and an inner diameter of 2 mm to 6 mm.

13. The method of claim 9, wherein the rod electrode is formed of metal.

14. The method of claim 13, wherein the rod electrode is formed of metallic molybdenum.

15. The method of claim 9, wherein the purge gas fed from the lower opening of the rod electrode is discharged through the upper opening of the rod electrode into the rotary drum.

16. The method of claim 9, wherein at least one of a lower side section and a bottom section of the rotary drum is provided with an outlet port that extends through the rotary drum and wherein the purge gas, after flowing into the rotary drum through the rod electrode, is discharged through the outlet port into the chamber.

17. The method of claim 9, wherein the purge gas includes at least one gas selected from the group consisting of a hydrogen gas, a nitrogen gas, and an inert gas.
